(19) United States
(12) Patent Application Publication
(10) Pub. No.: US 2011/0132423 A1
(43) Pub. Date: Jun. 9, 2011

(54) Photovoltaic solar module comprising bifacial solar cells

(75) Inventors: Toshio Joge, Ibaraki-ken (JP); Rodolfo J. Magasrevy, Weston, FL (US)

(73) Assignee: Gamma Solar, Weston, FL (US)

(21) Appl. No.: 12/311,733

(22) PCT Filed: Oct. 11, 2007
(86) PCT No.: PCT/US07/21739

§ 371 Date: May 27, 2010

Related U.S. Application Data
(60) Provisional application No. 60/850,986, filed on Oct. 11, 2006.
(60) Provisional application No. 60/850,987, filed on Oct. 11, 2006.

(51) Int. Cl. H01L 31/05; H01L 31/042; B23K 31/02; B23K 1/00; H01L 31/18; H01L 31/0216; H01L 21/22

(52) U.S. Cl. 136/244; 228/179.1; 438/67; 438/72; 438/542; 257/E31.119; 257/E21.135

(57) ABSTRACT

A photovoltaic solar cell module comprises a plurality of bifacial solar cells and electrical conductors. Each bifacial solar cell comprises a plurality of bus-bar contacts. A phosphorous silicon glass layer is formed on one side of the bifacial cell by phosphorous diffusion, and a boron silicon glass layer is formed on the other side of the bifacial cell by boron diffusion. The phosphorous diffusion and the boron diffusion are conducted by a face-to-face diffusion method. The combination of the two gettering methods substantially increases the minority carrier life time of the bifacial solar cell.

This application claims the benefit of U.S. Provisional Patent Application Nos. 60/850,986, filed on Oct. 11, 2006, and 60/850,987, filed on Oct. 11, 2006, which are hereby incorporated by reference for all purposes as if fully set forth herein.

### BACKGROUND OF THE INVENTION

1. Field of the Invention

The present invention relates to photovoltaic solar cell modules comprising bifacial solar cells and manufacturing methods thereof.

2. Discussion of the Related Art

In a conventional mono-facial silicon solar cell, the rear side of the cell is covered by an aluminum contact. The monofacial cell is only photosensitive with respect to light impinging on the front side of the cell. In contrast, a bifacial solar cell is photosensitive on front and rear surfaces and, therefore, can generate electricity by receiving light on both surfaces.

In order to maintain integrity, a conventional solar cell has a thickness of about 250 μm to 300 μm. The amount of silicon used directly affects manufacturing costs. The cost of a conventional silicon substrate wafer is about 70% of the total cost of a solar cell, and 75% of the total cost of a solar cell module. Therefore, reducing the thickness of the solar cell can significantly reduce the production cost of the solar cell and solar cell modular.

### SUMMARY OF THE INVENTION

Accordingly, the present invention is directed to bifacial solar cells and photovoltaic solar modules comprising bifacial solar cells that substantially obviate the aforementioned problems due to limitations and disadvantages of the related art.

An advantage of the present invention is to provide less costly bifacial solar cells and photovoltaic solar modules comprising bifacial solar cells.

Another advantage of the present invention is to provide less costly bifacial solar cells and photovoltaic solar modules without compromising the structural integrity of the solar cells.

Additional features and advantages of the invention will be set forth in the description which follows. These and other advantages, in accordance with the purpose of the present invention, as embodied and broadly described, are achieved by a photovoltaic solar cell module having a plurality of bifacial solar cells and electrical conductors. Each electrical conductor connects an anode side of a first bifacial solar cell and a cathode of a second bifacial solar cell. The anode side and the cathode side of the first and second bifacial solar cells substantially are in the same plane and face substantially the same direction.

The aforementioned and other advantages are also achieved by a photovoltaic solar cell module having a plurality of bifacial solar cells and electrical conductors. Each bifacial solar cell comprises a plurality of bus-bar contacts. Each bus-bar contact has a plurality of soldering portions and gaps, and the electrical conductors is soldered on the bus-bar contacts at the soldering portions.

The aforementioned and other advantages are also achieved by a method of manufacturing a photovoltaic solar cell module. The method comprises

providing a plurality of bifacial solar cells and connecting the bifacial solar cells via a plurality of electrical conductors. Each electrical conductor connects an anode side of a first bifacial solar cell and a cathode of a second bifacial solar cell. The anode side and the cathode side of the first and second bifacial solar cells substantially are in the same plane and face substantially the same direction.

The aforementioned and other advantages are also achieved by a method of manufacturing a bifacial solar cell. The method comprises etching a silicon substrate resulting in random pyramids or other shape of texture structure; conducting boron diffusion on a sear side of the silicon substrate to form a boron silicon glass layer thereon; conducting phosphorous diffusion on a front side of the silicon substrate to form a phosphorous silicon glass layer thereon; conducting edge isolation for etching the edge of the silicon substrate by a plasma etcher; attaching a front contact on the front side of the silicon substrate; attaching a rear contact on the rear side of the silicon substrate; and heating the silicon substrate with the front contact and rear contact at a temperature of approximately 740° C. to 790° C. for approximately one minute.

The aforementioned and other advantages are also achieved by a face-to-face diffusion method. The method comprises overlaying a first side of a first silicon substrate on a first side of a second silicon substrate; conducting boron diffusion on a second side of the first silicon substrate and on a second side of the second silicon substrate to form boron silicon glass layers thereon; rearranging the first and second silicon substrates by overlaying the second side of the first silicon substrate on the second side of the second silicon substrate; and conducting phosphorous diffusion on the first side of the first silicon substrate and on the first side of the second silicon substrate to form phosphorous silicon glass layers thereon.

It is to be understood that both the foregoing general description and the following detailed description are exemplary and explanatory and are intended to provide further explanation of the invention as claimed.

### BRIEF DESCRIPTION OF THE DRAWINGS

The accompanying drawings, which are included to provide a further understanding of the invention and are incorporated in and constitute a part of this specification, illustrate exemplary embodiments of the invention and together with the description serve to explain the principles of the invention. In the drawings:

FIG. 1 illustrates a cross sectional view of an exemplary bifacial solar cell;

FIG. 2 illustrates an exemplary manufacturing process for a bifacial solar cell;

FIG. 3A, FIG. 3B, and FIG. 3C illustrate an exemplary face-to-face diffusion method;

FIG. 4 illustrates the change in life time of a bifacial solar cell during the manufacturing process of the present invention;

FIG. 5 illustrates the surface reflectance of two bifacial solar cells in accordance with the present invention;

FIG. 6 illustrates a solar module comprising conventional solar cells in accordance with the related art.

FIG. 7 illustrates a cross sectional view of the solar module comprising conventional solar cells in accordance with the related art.

FIG. 8A illustrates a front side contact pattern for a conventional solar cell in accordance with the related art;

FIG. 8B illustrates a rear side contact pattern for a conventional solar cell in accordance with the related art;

FIG. 9 illustrates an exemplary photovoltaic solar module comprising bifacial solar cells in accordance with the present invention;

FIG. 10 illustrates a cross sectional view of an exemplary photovoltaic solar module comprising bifacial solar cells in accordance with the present invention;

FIG. 11 illustrates a contact pattern of an exemplary photovoltaic solar module comprising bifacial solar cells in accordance with the present invention;

FIG. 12 illustrates a cross sectional view of an exemplary bifacial solar cell with soldered interconnection ribbons in accordance with the present invention.

### DETAILED DESCRIPTION OF THE ILLUSTRATED EMBODIMENTS

Reference will now be made in detail to exemplary embodiments of the present invention, with further reference to the accompanying drawings. It will be apparent to those skilled in the art that various modifications and variations are possible without departing from the spirit or scope of the invention.

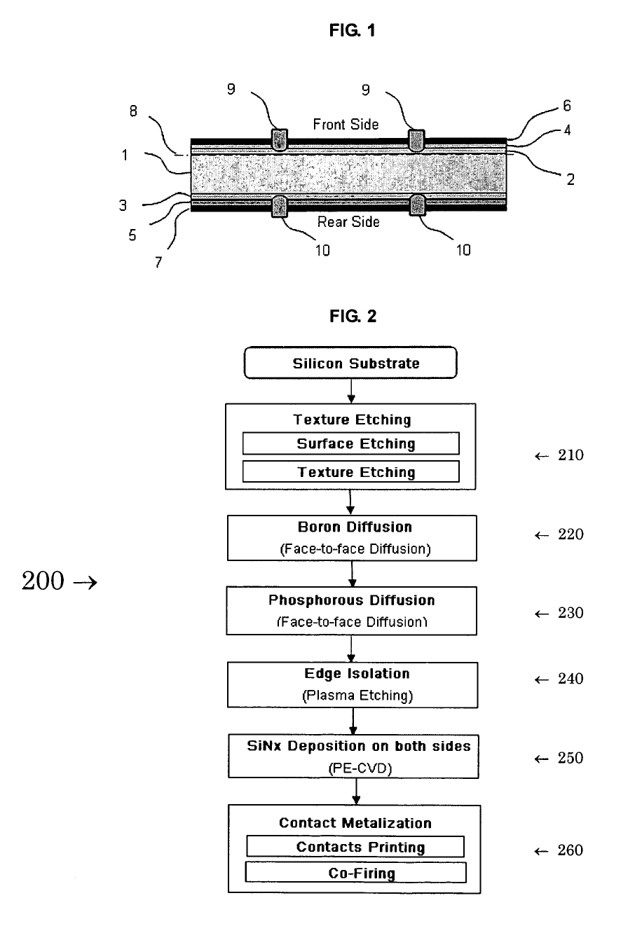

FIG. 1 illustrates a cross sectional view of an exemplary bifacial solar cell. The bifacial solar cell comprises a silicon substrate 1. The silicon substrate 1 can be mono-crystalline silicon, multi-crystalline silicon, or another similar semiconductor material, and it can be either p- or n-type. The silicon substrate 1 here is a p-type substrate, as an example. The silicon substrate 1 is coated with an n⁺ layer 2 on the front side and a p⁺ layer 3 on the rear side. A phosphorous silicon glass (PSG) layer 4 is deposited on the n⁺ layer 2. A boron silicon glass (BSG) layer 5 is deposited on the p⁺ layer 3. The junction 8, which forms a diode in the bifacial solar cell, is an n⁺p junction in the front side. Optionally, a front side anti-reflection coating layer 6 may be formed on the PSG layer 4, and a rear side anti-reflection coating lay 7 may be formed on the BSG layer 5. The anti-reflection coating layers can be SiNₓ or another suitable material. A front side contact 9 is then formed on the front side, and a rear side contact 10 is formed on the rear side.

A solar cell's efficiency is the percentage of power converted from absorbed light to electrical energy. To have high efficiency at the rear side, a long life time for minority carriers is required. The bifacial solar cell shown in FIG. 1 has high efficiency on the rear side. Thus, the bifacial solar cell has a bifaciality (i.e., a rear side efficiency to front side efficiency ratio) up to 100%. An n⁺pp⁺ BSF type bifacial solar cell with a thickness of 150 μm is used as a representative example here. One test shows that the front side efficiency is greater than or equal to 15.5% and the rear side efficiency is greater or equal to 15.0% in the best cell of a group of 70 n⁺pp⁺⁺ BSF type bifacial solar cells. The bifaciality of the 70 tested cells was approximately 95% on average and 97% in the best case. A p⁺nn⁺ BSF type bifacial solar cell using n-type FZ silicon substrate with resistivity of 10Ω·cm was also tested, and it also has a bifaciality up to 100%.

The bifacial solar cell of FIG. 1 has a thickness of approximately 100 μm to 200 μm, which is much thinner than that of conventional solar cells. Therefore, the production costs for bifacial solar cells can be reduced by reducing the size (i.e., thickness) of the silicon substrate because less silicon is used. The manufacturing process for making bifacial solar cells, such as the bifacial solar cell of FIG. 1, is described in detail below.

FIG. 2 illustrates an exemplary manufacturing process 200 for a bifacial solar cell, such as the bifacial solar cell of FIG. 1. In a first step 210, silicon substrate 1 is subject to an alkaline etching process resulting in the formation of random pyramids on both the front and the rear side of silicon substrate 1. The etching process improves the efficiency of the solar cell by minimizing the reflectance of the silicon substrate and removes Fe-contamination from the surface portion of silicon substrate 1.

In step 220, silicon substrate 1 is subject to a face-to-face boron diffusion procedure. The face-to-face procedure is discussed in detail below. During boron diffusion, the p⁺ layer 3 is formed on the rear side of the silicon substrate 1 and the BSG layer 5 is formed on the p⁺ layer 3.

In step 230, silicon substrate 1 is subject to a face-to-face phosphorous diffusion procedure. During phosphorous diffusion, the n⁺ layer 2 is formed on the front side of the silicon substrate 1 and the PSG layer 4 is formed on the n⁺ layer 2.

In step 240, silicon substrate 1 with the PSG and BSG layers is further subject to an edge isolation process. The silicon substrate 1 with the PSG and BSG layers is set in a carrier in a coin stack state, together with a top buffer wafer and a bottom buffer wafer. The silicon substrate 1 with the PSG and BSG layers is then placed in a plasma etcher. The surface of the coin stack is etched out, for example, 100 micrometers in depth. However, it may be possible to etch out more or less of the surface. The silicon substrate 1 with PSG and BSG layers is edge-isolated thereby.

In step 250, the front anti-reflective coating layer 7 and the rear side anti-reflective coating layer 8 are deposited by Plasma Enhanced Convention Vapor Deposition (PE-CVD). The anti-reflective coating layers 7 and 8 can be SiNₓ or another similar material.

In step 260, the front contact 9 and the rear contact 10 are screened-printed on silicon substrate to form the bifacial solar cell. The bifacial solar cell is then co-fired at a peak temperature of approximately 740 to 790° C. in a firing furnace for approximately one minute, although it might take less than one minute. Preferably, the peak temperature is approximately 760 to 780° C.

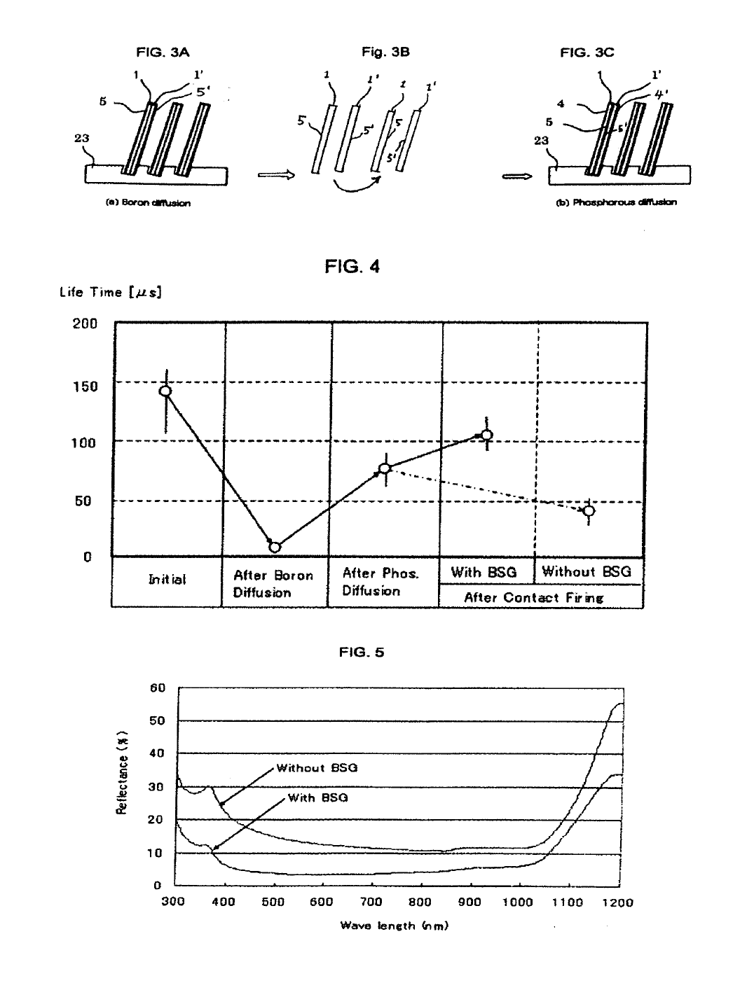

FIGS. 3A, 3B, and 3C illustrate an exemplary face-to-face diffusion method that may be used in steps 230 and 240. First, silicon substrate pairs are formed by overlaying the front side of silicon substrate 1 on the front side of silicon substrate 1′ for each pair. The silicon substrate pairs are then arranged in a wafer tray 23, as shown.

FIG. 3A more specifically illustrates the face-to-face boron diffusion process. Here, boron is diffused, in order to form BSG layer 5 and BSG layer 5′, on the rear side of silicon substrate 1 and silicon substrate 1′, respectively. The rear side of each silicon substrate works as a mask against possible auto-doping on the front side.

FIG. 3B more specifically illustrates that the silicon substrate pairs are then rearranged by overlaying the rear side of each silicon substrate 1 on the rear side of a corresponding silicon substrate 1′.

FIG. 3C more specifically illustrates the face-to-face phosphorous diffusion process. After the silicon substrate pairs are rearranged, phosphorous is diffused on the front sides of silicon substrate 1 and silicon substrate 1′ for each pair, thus forming PSG layer 4 and PSG layer 4′, as shown. An n⁺pp⁺ structure with a PSG layer on the n⁺ layer and a BSG layer on the p⁺ layer can be cost effectively formed by using this face-to-face diffusion method. Furthermore, the BSG layers function as a mask against the phosphorous auto-doping in addition to the face-to-face method effect.

In order for a solar cell to have high efficiency, a long minority carrier life time is needed. The minority carrier life time of the bifacial solar cell should be greater than 100 μs. FIG. 4 illustrates the change in minority carrier life time of the bifacial solar cell during the manufacturing process set forth above and illustrated in FIG. 2. As shown, the life time drops below 10 μs after the boron diffusion step 220. Gettering of interstitial Fe atoms plays an important role in increasing the life time. In accordance with exemplary embodiments of the present invention, two gettering methods are used here. The first gettering method is associated with the phosphorous diffusion step 230. The second gettering method is associated with the co-firing process of step 260. As shown in FIG. 4, the minority carrier life time recovers to about 75 μs after phosphorous gettering. The minority carrier life time increases even further to more than 100 μs after the second gettering method associated with the co-firing process of step 260. The second gettering method requires co-firing the bifacial solar with a BSG layer at a peak temperature of approximately 740 to 790° C. in a firing furnace for approximately one minute. Also shown in FIG. 4, a bifacial solar cell without a BSG layer is co-fired at the same condition (dotted line). The minority carrier life time of the cell without a BSG layer drops below 50 μs after the co-firing step 260. The combination of the two gettering methods substantially increases the minority carrier life time of the bifacial solar cell.

FIG. 5 illustrates the reflectance of the surface of two bifacial solar cells manufactured in accordance with the method illustrated in FIG. 2. The thickness of the anti-reflection layer should be approximately 85 nm. As shown in FIG. 5, the reflectance of a bifacial solar cell that has an anti-reflection layer in combination with a BSF layer is greatly improved compared to a bifacial solar cell without a BSF layer. The bifacial solar cell may have an anti-reflection layer on either the front surface or the rear surface, or both front and rear surfaces. For a bifacial cell having both front and rear side anti-reflection layers, two PE-CVD steps would be required. Although reflection is improved, the additional PE-CVD step may increase manufacturing cost.

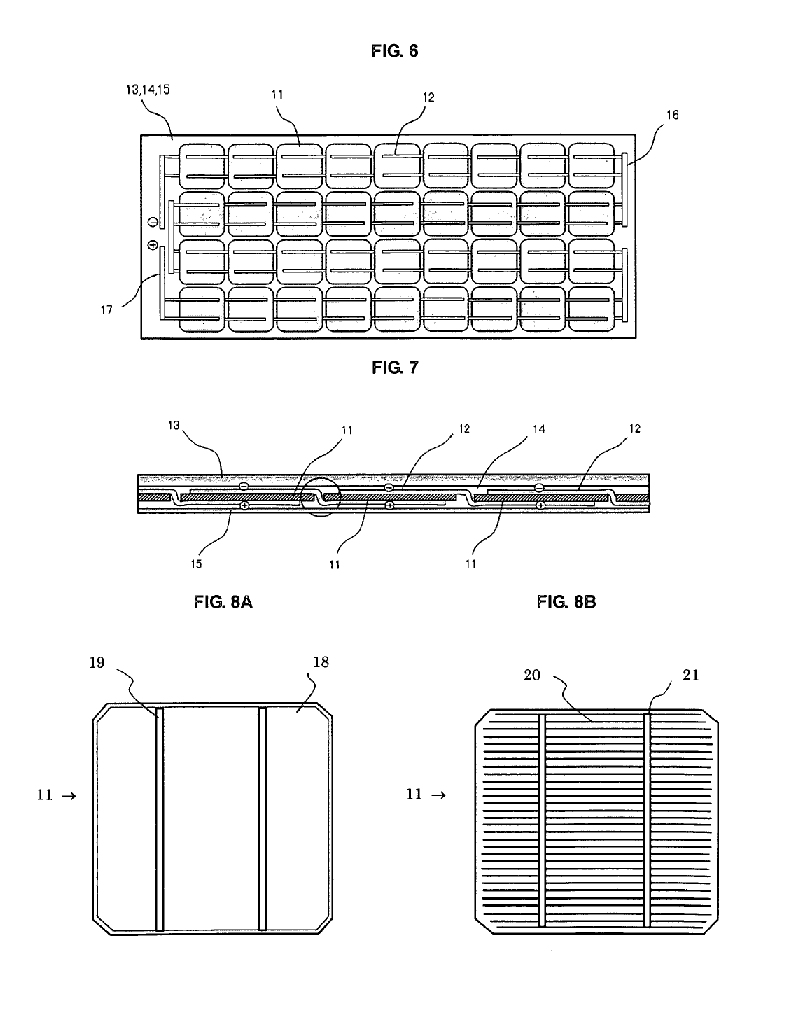

FIG. 6 illustrates a conventional solar cell module comprising conventional solar cells. FIG. 7 illustrates a cross sectional view of the solar cell module of FIG. 6. As shown, the solar cell module includes a plurality of conventional solar cells 11, a tempered glass plate 13, ethylene vinyl-polymer acetate (EVA) 14, a back-sheet 15, electrical conductors 12, string connection ribbons 16, terminal ribbons 17 and a terminal box (not shown). The cells 11 here are conventional mono-facial cells, but they could be conventional bifacial cells. As the cells 11 are connected in series by string connection ribbons 16, the electrical conductors 12 are at one end soldered on a front side bus-bar contact of each cell, and at the other end, soldered to the rear side bus-bar contact of an adjacent cell. If the solar cells are too thin, the likelihood that the cells will break is quite high, because the point at which the electrical conductors 12 cross the cells 11 is susceptible to damage due to heat expansion of the cells 11 and the electrical conductors 12, and other reasons.

FIGS. 8A and 8B illustrate front side and rear side contact patterns, respectively, of the conventional solar cells. As shown, the mono-facial cell 11 has a rear aluminum contact 18, rear silver contact 19, front finger contacts 20, and two buss-bar contacts 21. The rear side of the mono-facial cell 11 is covered by the rear aluminum contact 18, so the cell 11 can not generate electricity when it is illuminated on the rear side. The thickness of the silicon substrate in a conventional cell 11, such as solar cell, is approximately 250 μm to 320 μm and the thickness of the rear aluminum contact 18 is approximately 20 μm. If a thinner silicon substrate is used, cell 11 will be susceptible to warping due to differential rates of heat expansion across the surface of the cell. The cell 11 is also susceptible to breaking when it cools after the contact is fired in a firing furnace.

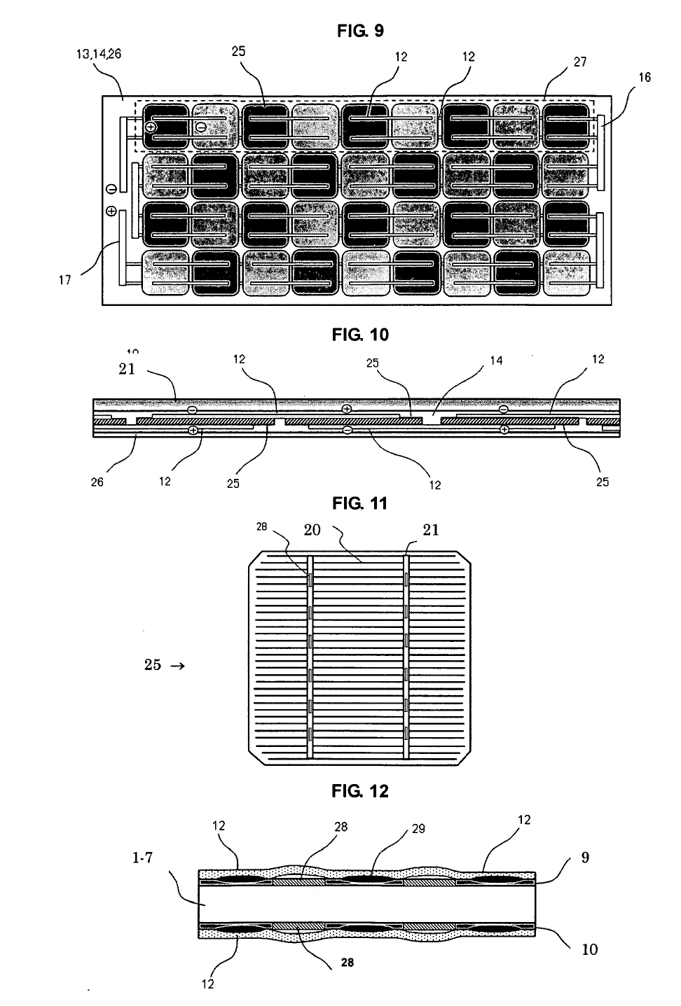

FIG. 9 illustrates an exemplary photovoltaic solar module comprising bifacial solar cells. The bifacial solar cells may be manufactured in accordance with the exemplary method described above and set forth in FIG. 2. FIG. 10 illustrates a cross sectional view of the photovoltaic solar module shown in FIG. 9. The solar module includes a plurality of bifacial solar cells 25, electrical conductors 12, string connection ribbons 16, terminal ribbons 17, a tempered glass plate 10, EVA 14, a transparent back-sheet 26 (or glass plate) and a terminal box (not shown). The electrical conductors may be interconnection ribbons and other similar connection means.

As shown in FIG. 9, the bifacial cells 25 are connected in series by electrical conductors 12 to form a single string 27 of solar cells. In this example, there are four such strings connected by string connection ribbons 16 and terminal ribbons 17. Because the bifacial cells 25 generate electricity by receiving light on both the front and rear side, the bifacial cells 25 are arranged such that the orientation of the cells alternate front side up (light shading), rear side up (dark shading), front side up, and so forth. The front side here is designated as the anode side and the rear side here is designated as the cathode side, as an example. The electrical conductors 12 connect adjacent bifacial cells 25 in substantially the same plane, and do not cross from one side of the photovoltaic solar module to the other side of the photovoltaic solar module as is the case with the solar module of FIG. 6. Because the electrical conductors 12 do not cross from one side of the photovoltaic module to the other, there are no stress points on the bifacial solar cells 25 as is the case with the conventional solar module of FIG. 6. Therefore, the bifacial solar cells 25 that make up the photovoltaic module illustrated in FIGS. 9 and 10, which may be manufactured in accordance with the exemplary method set forth in FIG. 2, are far less susceptible to breakage. Because the bifacial solar cells are far less susceptible to breakage, they can be thinner (approximately 100 μm-200 μm) as compared with conventional solar cells. As stated above, the use of the thinner solar cells substantially reduces manufacturing costs because less silicon is required, and because high yields are realized due to less breakage. However, it should be pointed out that thicker conventional bifacial solar cells could be used in the photovoltaic solar module shown in FIGS. 9 and 10.

FIG. 11 illustrates an exemplary contact pattern for the photovoltaic solar cells 25. FIG. 12 is a cross sectional view of one bifacial solar cell 25 with soldered electrical conductors 12. A grid contact pattern is applied to both sides of the bifacial solar cell 25. Each bifacial cell 25 has finger contacts 20 and two bus-bar contacts 21. The bus-bar contacts 21 have a width of about 2 mm. The bus-bar contacts 21 also have several soldering portions 29 and several gaps 28 having a width of approximately 1.5 mm, in a preferred embodiment. The gaps 28 may be of a rectangular shape, an oval shape or another similar shape. The electrical conductors 12 have a width of approximately 1.5 mm, in a preferred embodiment. Each electrical conductor 12 is soldered on two bus-bar contacts 21 of two bifacial solar cells 25 at the soldering portions 29 to connect the two cells 25. In the course of the soldering, the temperature is raised to approximately 130° C., and then is lowered to room temperature. During the module fabrication process, the temperature is also raised and then lowered. The electrical conductor 12 is soldered at the soldering portions 29 on the bus-bar contact 21, not at the gaps 29. Because the electrical conductors 12 are floating on gaps 28 at a high temperature, the electrical conductors 12 impose small stresses on the cells 25 when they shrink at a lower temperature. Therefore, the cells 25 are far less susceptible to breakage, and they can be made thinner than conventional solar cells, which, as stated above, substantially reduces manufacturing costs as less silicon is required.

What is claimed is:

1. A photovoltaic solar cell module comprising:
a plurality of bifacial solar cells; and
a plurality of electrical conductors;
wherein each electrical conductor connects an anode side of a first bifacial solar cell and a cathode side of a second bifacial solar cell, the anode side and the cathode side of the first and second bifacial solar cells substantially being in the same plane and facing substantially the same direction.

2. The photovoltaic solar cell module of claim 1,
wherein adjacent bifacial solar cells are oriented the anode side facing the same direction and the cathode side facing the same direction, respectively.

3. The photovoltaic solar cell module of claim 1,
wherein each bifacial solar cell comprises a plurality of bus-bar contacts, each bus-bar contact having a plurality of soldering portions and gaps, and the electrical conductors being soldered on the bus-bar contacts at the soldering portions.

4. The photovoltaic solar cell module of claim 3,
wherein the gaps are rectangular or oval shaped.

5. The photovoltaic solar cell module of claim 1,
wherein the electrical conductors are interconnection ribbons.

6. The photovoltaic solar module of claim 1,
wherein each bifacial solar cell has a thickness of approximately 100 μm to 200 μm.

7. A photovoltaic solar cell module comprising:
a plurality of bifacial solar cells; and
a plurality of electrical conductors;
wherein each bifacial solar cell comprises a plurality of bus-bar contacts, each bus-bar contact having a plurality of soldering portions and gaps, and the electrical conductors being soldered on the bus-bar contacts at the soldering portions.

8. The photovoltaic solar module of claim 7,
wherein the gaps are rectangular or oval shaped.

9. The photovoltaic solar module of claim 7,
wherein the electrical conductors are interconnection ribbons.

10. The photovoltaic solar module of claim 7,
wherein each bifacial solar cells has a thickness of approximately 100 μm to 200 μm.

11. A method of manufacturing a photovoltaic solar cell module comprising:
providing a plurality of bifacial solar cells; and
connecting the bifacial solar cells via a plurality of electrical conductors,
wherein each electrical conductor connects an anode side of a first bifacial solar cell and a cathode side of a second bifacial solar cell, the anode side and the cathode side of the first and second bifacial solar cells substantially being in the same plane and facing substantially in the same direction.

12. The method of claim 11,
wherein adjacent bifacial solar cells are oriented the anode side facing the same direction and the cathode facing the same direction, respectively.

13. The method of claim 11,
wherein each bifacial solar cell comprises a plurality of bus-bar contacts, each bus-bar contact having a plurality of soldering portions and gaps, and the electrical conductors being soldered on the bus-bar contacts at the soldering portions.

14. The method of claim 13,
wherein the gaps are rectangular or oval shaped.

15. The method of claim 11,
wherein the electrical conductors are interconnection ribbons.

16. The method of claim 11,
wherein each bifacial solar cell has a thickness of approximately 100 μm to 200 μm.

17. The method of claim 11 further comprising:
heating the bifacial solar cells and the electrical conductors to a temperature of approximately 130° C. and then cooling down to room temperature.

18. A method of manufacturing a bifacial solar cell comprising:
etching a silicon substrate resulting in random pyramids or other shape of texture structure;
conducting boron diffusion on a sear side of the silicon substrate to form a boron silicon glass layer thereon;
conducting phosphorous diffusion on a front side of the silicon substrate to form a phosphorous silicon glass layer thereon;
conducting edge isolation for etching the edge of the silicon substrate by a plasma etcher;
attaching a front contact on the front side of the silicon substrate;
attaching a rear contact on the rear side of the silicon substrate; and
heating the silicon substrate with the front contact and rear contact at a temperature of approximately 740° C. to 790° C. for approximately one minute.

19. The method of claim 18 further comprising:
depositing anti-reflection layers on the front and rear sides of the silicon substrate.

20. The method of claim 18,
wherein the silicon substrate with the front contact and rear contact is heated at a temperature of approximately 760° C. to 780° C. for approximately one minute.

21. The method of claim 19,
wherein depositing anti-reflection layers is conducted by Plasma Enhanced Convention Vapor Deposition.

22. The method of claim 18,
wherein the front contact and the rear contact are screened-printed on the silicon substrate.

23. The method of claim 18,
wherein the phosphorous diffusion and boron diffusion are conducted by a face-to-face diffusion method.

24. A face-to-face diffusion method comprises:
overlaying a first side of a first silicon substrate on a first side of a second silicon substrate;
conducting boron diffusion on a second side of the first silicon substrate and on a second side of the second silicon substrate to form boron silicon glass layers thereon;
rearranging the first and second silicon substrates by overlaying the second side of the first silicon substrate on the second side of the second silicon substrate; and
conducting phosphorous diffusion on the first side of the first silicon substrate and on the first side of the second silicon substrate to form phosphorous silicon glass layers thereon.

25. The face-to-face diffusion method of claim 24 further comprising:
forming a silicon substrate pair with the first and second silicon substrates, and
arranging the silicon substrate pair on a wafer boat tray.
